(19) United States
(12) Patent Application Publication
(10) Pub. No.: US 2018/0033760 A1
(43) Pub. Date: Feb. 1, 2018

(54) CONDUCTIVE JOINING MATERIAL AND CONDUCTIVE JOINING STRUCTURE WHICH USE METAL PARTICLES AND CONDUCTIVE MATERIAL PARTICLES

(71) Applicant: NIPPON STEEL & SUMITOMO METAL CORPORATION, Tokyo (JP)

(72) Inventors: Shinji ISHIKAWA, Tokyo (JP); Yoshiaki HAGIWARA, Tokyo (JP); Norie MATSUBARA, Tokyo (JP); Tomohiro UNO, Tokyo (JP); Takayuki SHIMIZU, Kisarazu-shi (JP)

(73) Assignee: NIPPON STEEL & SUMITOMO METAL CORPORATION, Tokyo (JP)

(21) Appl. No.: 15/546,181

(22) PCT Filed: Jan. 26, 2016
(86) PCT No.: PCT/JP2016/052203

§ 371 Date: Jul. 25, 2017

(30) Foreign Application Priority Data
Jan. 26, 2015 (JP) 2015-012399

(51) Int. Cl. H01L 23/00; B23K 35/30; B23K 35/02

(52) U.S. Cl. CPC H01L 24/29; B23K 35/025; B23K 35/3006; B23K 35/302; B23K 35/3013; B23K 35/3033; H01L 24/27; H01L 2924/35121; H01L 2224/27505; H01L 2224/29239; H01L 2224/29244; H01L 2224/29247; H01L 2224/29255; H01L 2224/29284; H01L 2224/2928; H01L 2224/29271; H01L 2224/29266; H01L 2224/2927; H01L 2924/0424

(57) ABSTRACT

A conductive joining material and conductive joined structure for joining two joining members by a joining layer using metal nanoparticles at the time of which even if there is a difference in the amounts of heat expansion due to a difference in linear thermal expansion coefficients between these two joining members and further use at a high temperature is sought, it is possible to adjust the amount of heat expansion of the joining layer to a suitable value between the two joining members to ease the thermal stress occurring at the joining layer and possible to sufficiently hold the joint strength between the two joining members are provided.

A conductive joining material containing metal nanoparticles, microparticles of a conductive material, and a solvent, wherein the conductive material forming the microparticles has a linear thermal expansion coefficient smaller than the linear thermal expansion coefficient of the metal forming the nanoparticles and the microparticles of conductive material have an average particle size of 0.5 to 10 μm.

### TECHNICAL FIELD

The present invention relates to a conductive joining material using metal particles and particles of conductive material and a conductive joined structure, more particularly relates to a conductive joining material and conductive joined structure holding a high joining ability even when thermal stress is applied to the joined part.

### BACKGROUND ART

Metal particles with an average particle size of less than 1 μm, in particular 1 to 100 nm, are called “metal nanoparticles”. Metal nanoparticles have a high bondability caused by the fine particle size. It has been confirmed that the particles bond together at a far lower temperature than the melting point of the metal forming the metal nanoparticles. Further, the structural strength of the bonded member obtained is expected to be maintained until near the melting point of the metal. As the metal forming the metal nanoparticles, Ag is typical. In addition, Au, Cu, Ni, etc. may be mentioned (for example, PLT 1).

Metal nanoparticles are generally used as organic-metal composite nanoparticles having the structure of metal nanoparticles covered by organic shells made of organic substances. At room temperature, the organic shells can prevent self aggregation of metal nanoparticles and maintain their independent dispersed form. If the metal nanoparticles are supplied to the surfaces of the joining members as organic-metal composite nanoparticles and heated to a predetermined temperature to be fired, the organic shells are broken down and removed, the active surfaces of the metal nanoparticles are exposed and the low temperature sintering function is exhibited, and the metal nanoparticles are joined with each other and simultaneously joined with the surfaces of the joining members (NPLT 1).

In this regard, in the field of power semiconductors etc., power semiconductor modules comprising a semiconductor device etc. joined with an insulated circuit board and further including a base plate, terminals, etc. are being used in various electronic equipment. As art used for joining such semiconductor devices and insulated circuit boards, in the past mainly soldering has been used.

On the other hand, along with the recent technical advances in the field of power semiconductors, devices can now be used at higher temperatures (for example, 300° C. or so). Due to this, energy-saving power devices can be expected to soon be realized. Along with this, heat resistance at a higher temperature is being sought from the joined parts of the power semiconductor modules. However, with conventional solder joining techniques, there is the problem that it is not possible to secure joint strength at a high temperature.

Therefore, in the past as well, to solve such a problem in the soldering technique, the art of using the high bondability of metal nanoparticles to utilize them as the joining materials of semiconductor devices has been proposed. However, in the technical field of power semiconductors etc., in a joined structure comprised of two joining members joined with each other through a joining layer, when the joined structure rises in temperature or when it falls in temperature or when the two joining members forming the joined structure are heated to different temperatures, sometimes the joining layer is subjected to thermal stress, cracks and other defects form near the joint interface of the semiconductor device, and the joint strength falls.

That is, in the case of a joined structure using conventional metal nanoparticles, as shown in FIG. 1, between the joining surface 1a of the first joining member 1 (first joining surface) and the joining surface 2a of the second joining member 2 (second joining surface), a joining layer 3 comprised of a sintered metal obtained by sintering metal nanoparticles is formed. In this regard, however, when the first joining member 1 and the second joining member 2 forming such a joined structure are formed by materials having different linear thermal expansion coefficients or when these first joining member 1 and second joining member 2 are heated to different temperatures, if the semiconductor device is turned on/off in operation etc. and thereby the part having the joined structure rises in temperature or falls in temperature, a difference in the amounts of heat expansion inevitably occurs between the two first joining member 1 and second joining member 2 and thermal stress due to heat deformation occurs at the joining layer 3 joining these.

For example, in the joined structure shown in FIG. 1, when the first joining member 1 is a Si semiconductor device and the second joining member 2 is a Cu circuit layer, in particular the difference in heat expansion between the joining layer 3 obtained by sintering Ag, Au, Cu, Ni, and other metal nanoparticles and the Si semiconductor device of the first joining member 1 became larger than the difference in heat expansion between the Cu circuit layer of the second joining member 2 and the joining layer 3, the thermal stress accompanying heat deformation could not be completely eased, cracks and other defects occurred near the joint interface of the Si semiconductor device of the first joining member 1 (first joining surface 1a), and the joint strength fell. Further, when fabricating a joined structure such as shown in FIG. 1 comprised of a first joining member 1 of a Si semiconductor device and a second joining member 2 of a joined Cu circuit layer as well, when sintering the metal nanoparticles by 350° C. or so heat treatment, the Si semiconductor device of the first joining member 1 and the Cu circuit layer of the second joining member 2 are respectively in states extended in lengths by exactly the amounts of heat expansion corresponding to 350° C. If sintering proceeds in this state, a joining layer 3 is formed, then the temperature is lowered to ordinary temperature, due to the difference in the amounts of heat contraction of the first joining member 1 and the second joining member 2, thermal stress occurs due to the thermal deformation inside the joining layer 3 formed. In general, the firing temperature is higher than the rise in temperature due to the on/off operation of the semiconductor device, so even with one instance of thermal stress at the time of fabrication of the joined structure, cracks formed in the joining layer 3 and the joining layer 3 using the metal nanoparticles sometimes became insufficient in shear strength.

Further, even if the two joining members are heated to mutually different temperatures, thermal stress occurs at the joining layer. When using solder as the joining material, since usually solder has a high ductility, the ductility of the solder at the joining layer absorbs the difference in the amount of heat expansion of the joining members at the two sides of the same and can ease the thermal stress, but when using metal nanoparticles as the joining material, since the ductility of a joining layer comprised of a sintered metal of metal nanoparticles is lower than solder, sometimes the difference in the amounts of heat expansion of the two joining members cannot be completely absorbed, the thermal stress accompanying heat deformation cannot be eased, defects occur at the joining layer, and the joint strength falls.

Further, in the past as well, in the art utilizing such metal nanoparticles as the joining material for semiconductor devices etc., various attempts have been made to solve these problems. For example, PLT 2 proposes to eliminate the thermal stress occurring at a joining layer formed using metal nanoparticles by increasing the thickness of the joining layer. In the examples, the thickness of the joining layer is made 100 m or more. However, if making the thickness of the joining layer greater, when using metal nanoparticles comprised of Ag, Au, Cu, or Ni nanoparticles, the separate problem arises that the heat expansion of the joining layer formed by sintering these itself becomes too large.

That is, in the most general configuration of a power semiconductor module, the semiconductor device is made of Si (linear thermal expansion coefficient=about 3×10⁻⁶/K) or SiC (linear thermal expansion coefficient=about 5×10⁻⁶/K). Further, the circuit layer of the insulated circuit board is made of Cu (linear thermal expansion coefficient=about 17×10⁻⁶/K). Further, when these are joined by a nanoparticle material comprised of Ag (linear thermal expansion coefficient=about 19×10⁻⁶/K), Au (linear thermal expansion coefficient=about 14×10⁻⁶/K), Cu (as stated above), Ni (linear thermal expansion coefficient=about 13×10⁻⁶/K), and other metals, there is not that great a difference in the linear thermal expansion coefficient between the Cu circuit layer and the metal nanoparticle material, but there is a large difference in the linear thermal expansion coefficient between the semiconductor device and the metal nanoparticle material. For this reason, if a joining layer made of a sintered metal body of metal nanoparticles is used to strongly join a semiconductor device and insulated circuit board, a large thermal stress due to the difference in the amounts of heat expansion occurs particularly at the joint interface of the joining layer and the semiconductor device and the joint interface is liable to peel apart or the semiconductor device is liable to break.

### CITATION LIST

### Patent Literature

PLT 1: Japanese Patent Publication No. 2013-012693A
PLT 2: Japanese Patent Publication No. 2011-041955A Nonpatent Literature
NPLT 1: “Joining Technology Using Metal Nanoparticles”, Surface Technology, vol. 59, no. 7, 2008, pp. 443 to 447

### SUMMARY OF INVENTION

### Technical Problem

The present invention has as its object the provision of a metal joining material and metal joined structure for joining two joining members by a joining layer using metal nanoparticles at the time of which even if there is a difference in the amounts of heat expansion due to a difference in linear thermal expansion coefficients between these two joining members and further use at a high temperature (for example, 300° C. or so) is sought, it is possible to adjust the amount of heat expansion of the joining layer to a suitable value between the two joining members to ease the thermal stress occurring at the joining layer and possible to sufficiently hold the joint strength between the two joining members.

### Solution to Problem

That is, the gist of the present invention is as follows.

(1) A conductive joining material containing metal nanoparticles, microparticles of a conductive material, and a solvent, wherein the conductive material forming the microparticles has a linear thermal expansion coefficient smaller than the linear thermal expansion coefficient of the metal forming the nanoparticles and the microparticles of conductive material have an average particle size of 0.5 to 10 μm.
(2) The conductive joining material according to (1), wherein the difference in linear thermal expansion coefficient between the metal forming the nanoparticles and the conductive material forming the microparticles is 5×10⁻⁶/K or more.
(3) The conductive joining material according to (1) or (2), wherein the metal nanoparticles are any one of Ag, Au, Cu, and Ni.
(4) The conductive joining material according to any one of (1) to (3), wherein the microparticles of conductive material are one or more of a metal or metal boride.
(5) The conductive joining material according to any one of (1) to (4), wherein the microparticles of conductive material are one or more of any of W, Mo, Cr, TiB₂, and ZrB₂.
(6) The conductive joining material according to any one of (1) to (5), wherein 10 to 80 mass % of the total of the metal nanoparticles and microparticles of conductive material contained in the conductive joining material is comprised of the microparticles of conductive material.
(7) A joining method using a conductive joining material comprising placing a conductive joining material according to any of (1) to (6) between the first joining member and second joining member and heating it to 450° C. or less to join the first joining member and the second joining member.
(8) A conductive joined structure obtained by using a conductive joining material according to any one of (1) to (6) to join a first joining member and a second joining member, wherein 2 to 90 mass % of the conductive material derived from the microparticles and the metal derived from the metal nanoparticles in the cross-section in the joining direction is the conductive material.
(9) The conductive joined structure according to (8), wherein a difference in linear thermal expansion coefficients of the metal and the conductive material is 5×10⁻⁶/K or more.
(10) The conductive joined structure according to (8) or (9), wherein the metal is any of Ag, Au, Cu, and Ni.
(11) The conductive joined structure according to any one of (8) to (11), wherein the conductive material is one or more of W, Mo, Cr, TiB₂, and ZrB₂.

### Advantageous Effects of Invention

According to the conductive joined structure of the present invention, the joining layer formed between the first joining member and the second joining member is formed by a sintered conductor including a metal component derived from metal nanoparticles and a conductive material with a linear thermal expansion coefficient smaller than the linear thermal expansion coefficient of this metal. Even if the heating temperature is a low temperature of 450° C. or less, a sufficient joint strength is obtained by the sintered metal derived from metal nanoparticles, the sintered conductor derived from the conductive microparticles can be used to adjust the heat expansion characteristic of the joining layer to a suitable state between the heat expansion characteristics of the first joining member and the second joining member, the difference in the amount of heat expansion between the first joining member and the joining layer and between the joining layer and the second joining member when the conductive joined structure is heated to a predetermined temperature can be reduced as much as possible, and as a result a drop in the joint strength due to the heat history can be prevented.

### BRIEF DESCRIPTION OF DRAWINGS

FIG. 1 is a cross-sectional view showing an example of a conventional metal joined structure.

FIG. 2 is a cross-sectional view showing an example of a metal joined structure of the present invention.

FIG. 3 is a cross-sectional view showing another example of a metal joined structure of the present invention.

### DESCRIPTION OF EMBODIMENTS

The present invention provides a conductive joined structure comprised of a first joining member and a second joining member between which is provided a joining layer comprised of a sintered conductor containing microparticles of a conductive material and formed by sintering metal nanoparticles, wherein the conductive material forming the microparticles is comprised of a conductive material with a linear thermal expansion coefficient smaller than the linear thermal expansion coefficient of the metal forming the nanoparticles and has an average particle size of 0.5 to 10 μm.

In the present invention, the “metal nanoparticles” means metal fine particles with an average particle size of less than 1 μm, preferably 500 nm or less, preferably 5 nm or more, more preferably 100 nm or less. By using a sintered metal comprised of such metal fine particles sintered together as the joining layer of the joined structure, the metal fine particles are sintered together at a far lower temperature than the melting point of the melt (bulk metal) forming the metal nanoparticles, the first joining member and the second joining member can be joined, and the joint strength at the obtained joined structure can be maintained up to near the melting point of the metal. If the metal nanoparticles have an average particle size of 500 nm or less, the fluidity of the particles increases, so this is preferable. If 100 nm or less, the sinterability at a low temperature increases, so this is more preferable. Conversely, if smaller than 5 nm, the ratio of the oxides and organic shells at the surface of the metal nanoparticles becomes larger and the sinterability is liable to deteriorate and the joinability is liable to fall. Note that, the average particle size of the metal nanoparticles can be measured by the next method.

Method of Measurement of Particle Size of Metal Nanoparticles

A slurry obtained by dispersing the particles in ethanol, water, or another solvent at a high degree was coated on a sample stage and fully dried by vacuum drying or another method to prepare a sample for observation by a high resolution SEM (scanning electron microscope) or TEM (transmission electron microscope). The thus prepared observation sample was observed in a range of field of the diameter of particles×about 10 (for example, SEM image of field of 1270 nm×950 nm) to obtain an SEM image or TEM image. The obtained image was printed on paper and the length of the scale bar in the image and the diameters of the particles were measured by a ruler. The scale bar was used to convert the particle sizes to the actual sizes. These were arithmetically averaged to calculate the average particle size of the particles.

The element of the metal nanoparticles used in the present invention can be suitably selected in accordance with the materials of the two joining members to be joined together by the joining layer, but when preparing a power semiconductor module, one of Ag, Au, Cu, and Ni is suitable. These are often used for the joining layer of semiconductor devices not only because of the required excellent electrical conductivity and thermal conductivity, but also the correlation with the electrode structure at the back side of the semiconductor device. Therefore, depending on the electrode structure of the back side of the semiconductor device, it is also possible to use other elements. Further, the Ag, Au, Cu, and Ni metal nanoparticles may contain alloy ingredients other than those elements.

In the present invention, as shown in FIG. 2, between the joining surface 1a of the first joining member 1 (first joining surface) and the joining surface 2a of the second joining member 2 (second joining surface), a joining layer 3 is formed containing microparticles of conductive material 5 and comprising a metal nanoparticle phase 4 obtained by sintering metal nanoparticles. The inventors succeeded in solving the above problem by making the conductive material forming the microparticles 5 by a material with a smaller linear thermal expansion coefficient than the metal forming the nanoparticles. If a difference occurs between the amounts of heat expansion of the first joining member 1 and the second joining member 2, the amount of heat expansion of the joining layer 3 can be adjusted by the ratio of the volume of the conductive microparticles 5 with respect to the total of the metal nanoparticles and microparticles of conductive material 5, the difference of the amount of heat expansion between the first joining member 1 and second joining member 2 can be eased, and thereby a drop in the joint strength between the first joining member 1 and the second joining member 2 can be prevented in advance. Further, since the amount of heat expansion of the joining layer 3 can be adjusted to a suitable value between the amounts of heat expansion of the first joining member 1 and the second joining member 2, it is possible to reduce the difference in the amounts of heat expansion between the first joining member 1 and the second joining member 2 even with the extent of heat deformation of the low ductility joining layer comprised of a sintered metal of metal nanoparticles and prevent a drop in the initial joint strength between the first joining layer and the second joining layer.

In the present invention, “microparticles of conductive material” means conductive particles of an average particle size of 0.5 μm to 10 μm, preferably 1 μm to 3 μm. By dispersing such microparticles of conductive material in a joining layer of a joined structure comprised of sintered metal nanoparticles, it is possible to reduce the heat expansion/contraction compared with a joining layer obtained by sintering only metal nanoparticles and possible to maintain the joint strength of the joined structure at a strength giving sufficient reliability. If the average particle size of the microparticles of conductive material exceeds 10 μm, there is the problem that the particles deteriorate in fluidity. Further, if made 3 μm or less, the particles become densified and sinterability increases, so this is further preferred. On the other hand, if the average particle size of the microparticles of conductive material becomes smaller than 0.5 μm, the effect of reduction of the heat expansion/contraction becomes smaller. Further, the thermal conductivity and the electrical conductivity are liable to fall. Further, the microparticles of conductive material used in the present invention secure uniformity of heat conduction and electrical conduction, so to facilitate control for improving the filling rate of particles, the distribution of particle size should be narrower. Specifically, the distribution of particle size is preferably one with a standard deviation, calculated from all of the particle sizes measured by the following “Method of Measurement of Particle Size of Conductive Microparticles”, of “5 μm or less”. Further, the average particle size of the conductive microparticles can be found by using an SEM or TEM to directly observe the metal microparticles. Further, the conductive microparticles may be shaped not only as spherical shapes, but also as cube shapes, flat shapes, elliptical shapes, etc. In these cases, the longest side is defined as the particle size.

Method of Measurement of Particle Size of Conductive Microparticles

A slurry obtained by dispersing the conductive particles in ethanol, water, or another solvent at a high degree was coated on a sample stage and fully dried by vacuum drying or another method to prepare a sample for observation by an SEM or TEM. The thus prepared observation sample was observed in a range of field of the diameter of particles× about 10 (for example, SEM image of field of 16.5 μm×12.4 μm) to obtain an SEM image or TEM image. The obtained image was printed on paper and the length of the scale bar in the image and the diameters of the particles were measured by a ruler. The scale bar was used to convert the particle sizes to the actual sizes. These were arithmetically averaged to calculate the average particle size of the particles.

As the conductive material forming the microparticles of conductive material used in the present invention, it is possible to suitably select one from conductive materials having a linear thermal expansion coefficient smaller than the linear thermal expansion coefficient of the metal forming the nanoparticles in accordance with the type of the metal nanoparticles and the materials of the two joining members to be joined together by the joining layer etc., but to effectively ease the thermal stress occurring at the joining layer, it is preferably a metal having a difference from the linear thermal expansion coefficient of the metal forming the nanoparticles of 5×10⁻⁶/K or more, more preferably 8×10⁻⁶/K or more. For example, when preparing the power semiconductor module, it is preferably one or more types of materials selected from metals such as W (linear thermal expansion coefficient=about 4.5×10⁻⁶/K, electrical resistance (20° C.)=about 5.5×10⁻⁸ Ω·m), Mo (linear thermal expansion coefficient=about 4.8×10⁻⁶/K, electrical resistance (20° C.)=about 5.7×10⁻⁸ Ω·m), and Cr (linear thermal expansion coefficient=about 4.9×10⁻⁶/K, electrical resistance (20° C.)=about 13×10⁻⁸ Ω·m) and metal borides such as TiB₂ (linear thermal expansion coefficient=about (6.2 to 7.2)×10⁻⁶/K, electrical resistance (20° C.)=about 9×10⁻⁸ Ω·m) and ZrB₂ (linear thermal expansion coefficient=about (6.8 to 7.9)×10⁻⁶/K, electrical resistance (20° C.)=about 10×10⁻⁸ Ω·m). These are materials with a smaller linear thermal expansion coefficient than the metal in the temperature range from room temperature to the firing temperature of 450° C. Further, these microparticles of conductive material may be used suitably combined so as to give an amount of heat expansion of the joining layer easy to control considering the linear thermal expansion coefficients, average particle sizes, and ratios of content or may be used alone. Note that, even if elements other than these, if particles comprised of a material with a smaller linear thermal expansion coefficient compared with the metal forming the nanoparticles, an effect of reduction of the heat expansion/contraction can be expected. Further, the W, Mo, and Cr forming the microparticles of conductive material mean ones of contents of the elements in the particles (purity) of 99.5 mass % or more. If less than 0.5 mass %, unspecified unavoidable impurities may also be present. Further, the TiB₂ and ZrB₂ forming the microparticles of conductive material mean ones of contents of metal borides in the particles of 95 mass % or more. If less than 5 mass %, unspecified unavoidable impurities may also be present.

In the present invention, for example, to reduce the heat expansion/contraction ability of the joining layer and make it close to that (heat expansion/contraction ability) of the semiconductor device, it is sufficient to raise the ratio by volume of the microparticles of conductive material in the total volume of the metal nanoparticles and microparticles of conductive material contained in the conductive joining material of the present invention containing the metal nanoparticles and microparticles of conductive material. Further, it is sufficient to raise the ratio of content of the volume of the conductive material derived from the microparticles of conductive material to the metal derived from the metal nanoparticles in the sintered conductor obtained by sintering the conductive joining material and forming the joining layer, in other words, the ratio by volume of the microparticles of conductive material in the total volume of the metal nanoparticles and microparticles of conductive material forming the joining layer. Here, due to the firing, bonds are formed between the metal nanoparticles and other metal nanoparticles or between the metal nanoparticles and conductive microparticles, in particular metal bonds, and excellent joint strength is exhibited, but in general bonds are not formed between microparticles of conductive material and microparticles of conductive material at the 450° C. or less used for the firing temperature of metal nanoparticles. For this reason, the ratio of the microparticles of conductive material in the total volume of the metal nanoparticles and microparticles of conductive material contained in the conductive joining material has to be 80 vol % or less to obtain sufficient joint strength and reliability. Conversely, if the ratio of the microparticles of conductive material in the conductive joining material is less than 10 vol %, the heat expansion/contraction of the joining layer is liable to not be sufficiently reduced. Therefore, when the microparticles of the microparticles of conductive material contained in the conductive joining material are 10 vol % to 80 vol % of the total volume of the metal nanoparticles and microparticles of conductive material contained in the conductive joining material, preferably 30 vol % or more, still preferably 70 vol % or less, even with a material used in a high temperature and material used in an environment of a repeated temperature cycle of a high temperature and low temperature, a good joint strength can be maintained. Note that, the vol % of the microparticles in the conductive joining material can be found by the following method.

Method of Measurement of Vol % of Microparticles of Conductive Material with Respect to Total of Metal Nanoparticles and Microparticles of Conductive Material Contained in Conductive Joining Material

The density ρn of the metal forming the nanoparticles, the density ρm of the conductive material forming the microparticles, and the density ρy of the solvent are known. Here, the organic shells covering the nanoparticles are slight, so are ignored. The total mass Mn of the nanoparticles contained in the conductive material, the total mass Mm of the microparticles, and the mass My of the solvent are calculated by volume Vn of nanoparticles Vn=mass Mn÷density ρn, volume Vm of microparticles=mass Mm÷density ρm, and volume Vy of solvent=mass My÷density ρy. The total volume of the metal nanoparticles and microparticles of conductive material is Vn+Vm. The ratio of the microparticles of conductive material to the total volume is defined as Vm+(Vn+Vm). Further, the ratio of volume of the microparticles of conductive material in the total volume of the metal nanoparticles and microparticles of conductive material forming the joining layer (joined structure) cannot be directly measured, so instead a cross-section in the joining direction is obtained and the mass % of the conductive material to the total of the conductive material and metal material in that cross-section is measured.

Method of Measurement of Mass % of Conductive Material to Total of Conductive Material and Metal Material in Cross-Section in Joining Direction

First, the conductive joined structure is buried in a curable epoxy resin or other resin, the resin is cured, then this was cut vertical to the stacking direction from the first joining member through the joining layer to the second joining member to obtain a test piece. The cross-sectional surface is polished and in accordance with need processed by a CP (cross-section polisher) to prepare a test piece for SEM observation for observation of the cross-sectional surface.

Next, the prepared test piece is set on an SEM sample stage. The cross-sectional surface is observed under 5000 power. An image of the cross-sectional surface is obtained and is analyzed for assay of the elements by an EDX (energy dispersive X-ray spectroscope) attached to the SEM apparatus. If designating the mass % of the metal element A obtained by the quantitative analysis as Mₐ, the mass % of the metal element B of the conductive material (for example, in the case of TiB₂, indicating Ti) as M_{b}, and the mass % of the element C other than the metal of the conductive material (for example, in the case of TiB₂, indicating B) as M_{c} the mass % of the conductive material with respect to the total of the conductive material and metal material is defined as (M_{b}+M_{c})/(Mₐ+M_{b}+M_{c}). These operations are performed for three to 10 cross-sectional surfaces. The mass % is found by the arithmetic average.

In the present invention, the joining layer gives an overall joining power due to the bonds between the metal, so it is not necessary to make the joining layer contain a component other than the metal. As explained above, when forming the joining layer of the present invention, for example, the conductive joining material of the present invention, that is, the conductive particle paste, is coated on the joining surface of the first joining member and/or second joining member, these members are superposed, then the assembly is fired at 200° C. or more to sinter the metal nanoparticles and realize a joint. This conductive particle paste is comprised of metal nanoparticles and microparticles of conductive material made to disperse in an ether etc. In general, metal nanoparticles are covered by organic shells comprised of an organic substance. Therefore, the joining layer before firing contains a solvent component and components of the organic shells in the conductive particle paste. When fired at 200° C. or more, these solvent component and components of the organic shells break down. Parts vaporize and separate from the joining layer, while the remainders carbonize and remain in the joining layer, but these components which carbonize and remain do not contribute to the joining power of the joining layer. Therefore, even if the joining layer contains components other than the metal, the total volume derived from the metal nanoparticles and microparticles of conductive material contained in the joining layer need only be 50 vol % of the joining layer (when there are cavities or voids, excluding these parts) or more, preferably 70 vol % or more. Due to this, the effects of the present invention can be sufficiently exhibited. Note that, the thickness of the joining layer of the present invention is preferably 10 μm or more in the sintered conductor after firing, preferably 300 μm or less, more preferably 20 μm or more, still more preferably 150 μm or less.

When the conductive joined structure of the present invention forms for example a power semiconductor module, it is possible to arrange a first joining member comprised of a semiconductor device, further arrange a second joining member comprised of a metal board, resin board, or ceramic board, coat the conductive joining material of the present invention on the joining surfaces of these first joining member and/or second joining member and overlay the same, and heat the first joining member and/or second joining member and the conductive joining material together to fire the conductive joining material and sinter it to obtain the joining layer. As the metal board of the second joining member, an aluminum board, iron board, copper base board, stainless steel board, etc. may be mentioned. As the resin board of the second joining member, an epoxy resin board, phenol resin board, etc. may be mentioned. As the ceramic board of the second joining member, an alumina board, silicon carbide board, nitride-based board, etc. may be mentioned. A ceramic board may also be formed with a circuit comprised of copper or aluminum interconnects.

Note that, for example, when the second joining member is Cu and the metal nanoparticles are Au or Ni, since the linear thermal expansion coefficient is smaller in Au or Ni compared with Cu, if arranging the microparticles of conductive material to reduce the heat expansion/contraction of the joining layer, the difference in heat expansion between the second joining surface and the joining layer conversely becomes larger. For this reason, for example, as shown in FIG. 3, it is possible to coat the joining surface of the second joining member 2 (second joining surface) 2a with a joining material containing only metal nanoparticles, cause it to sinter to form a joining layer 3a comprised of a sintered metal, coat the joining layer 3a and/or the joining surface 1a of the first joining member 1 (first joining surface) with the conductive joining material of the present invention containing metal nanoparticles and microparticles of conductive material, and overlay and fire the members to form a joining layer 3 of the present invention comprised of a sintered conductor so as to join the first joining member 1 and the second joining member 2 by the joining layer 3a and joining layer 3. Due to this, as shown in FIG. 3, it is possible to mainly reduce the heat expansion of the first joining member 1 side of the joining layer 3.

In the present invention, the conductive joining material for forming the joining layer between the first joining member and second joining member includes the above metal nanoparticles, microparticles of conductive material, a solvent for dispersing these metal nanoparticles and microparticles of conductive material, and a protective agent for forming organic shells on the surfaces of the metal nanoparticles to prevent aggregation of metal nanoparticles. Further, as the solvent, one is selected from alcohol-based or ether-based solvents in accordance with the type of metal nanoparticles. Further, as the protective agent, one is selected from amine-based agents, carboxylic acid-based agents, and polymer-based agents. Further, in accordance with need, as the dispersant, one is selected from an amine-based one, carboxylic acid-based one, and alcohol-based one is selected. Further, in accordance with need, in these conductive joining materials, a dispersion aid may be selected and added from various conventionally known anion-based ones, cation-based ones, and nonionic-based ones. It is possible to give the conductive joining material the desired fluidity etc. The solvent content in this conductive joining material is usually 30 vol % to 90 vol %, preferably 50 vol % or more, more preferably 70 vol % or less.

The thus prepared conductive joining material of the present invention may be a slurry form, paste form, grease form, wax form, etc. For example, an air spray coater, roll coater, electrostatic spray coater, the squeegee method, mask printing, etc. may be used to coat the joining surface of the first joining member and/or second joining member with this in a layer, then fire this to remove the solvent etc. in the conductive joining material and further sinter the metal nanoparticles whereby a joining layer is formed where 2 to 90 mass % of the total of the conductive material derived from the microparticles and the metal derived from the metal nanoparticles at the cross-section in the joining direction is the conductive material.

Here, the conductive joining material is, for example, coated by an air spray coater, roll coater, electrostatic spray coater, the squeegee method, mask printing, etc. on the joining surface of the first joining member and/or second joining member in a layer form. Further, the conductive joining material coated on the joining surface of the first joining member and/or second joining member is fired by heating it to usually 200° C. to 450° C., preferably 250° C. to 400° C. If the heating temperature at the time of firing is less than 200° C., sometimes a sufficient joint strength cannot be obtained, while conversely, if the heating temperature is over 450° C., damage to the semiconductor device or resin board etc. is a concern. Further, when firing this conductive joining material to form a joining layer, a suitable pressure, preferably 0.1 MPa to 50 MPa, more preferably 2 MPa to 10 MPa, may be applied between the first joining member, conductive joining material, and second joining member at the same time as heating.

### EXAMPLES

### Examples 1 to 8 and Comparative Examples 1 to 3

Using the metal nanoparticles of the average particle sizes shown in Table 1 and the microparticles of conductive material of the average particle sizes shown in Table 1 and, further, using a solvent comprised of a terpene-based alcohol, metal nanoparticles and microparticles of conductive material were mixed in the ratios shown in Table 1 to prepare conductive joining materials with total ratios of these metal nanoparticles and microparticles of conductive material of 50 vol %. Note that, in Table 1, the components other than the metal nanoparticles and microparticles of conductive material were the above solvent and organic shells covering the metal nanoparticles.

Next, as the first joining member, a thickness 0.45 mm×vertical 3 mm×horizontal 3 mm size Si semiconductor device was used. One surface of this was formed with a total thickness 1.1 μm Ti/Ni/Au film by the sputtering method to form the first joining surface. Further, as the second joining member, a circuit board comprised of a thickness 0.32 mm×vertical 20 mm×horizontal 20 mm size alumina ceramic board on which a thickness 0.25 mm copper circuit layer was provided was used. On this copper circuit layer, a total thickness 5 μm Ni/Au plating layer was formed to form the second joining surface.

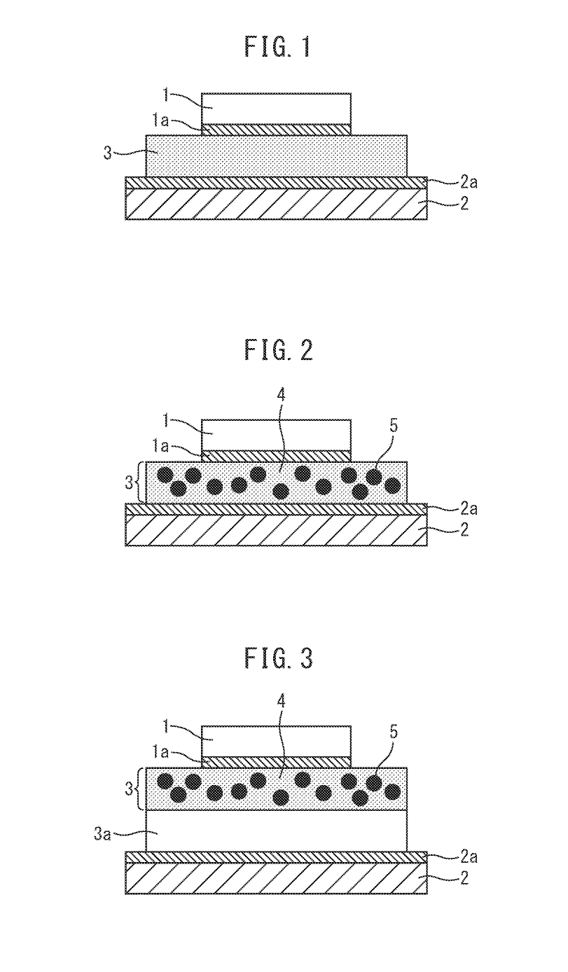

The above joining surface of the first joining member (first joining surface) was coated with the conductive joining material shown in Table 1 by the squeegee method, then the joining surface of the second joining member (second joining surface) was overlaid so as to sandwich the conductive joining layer coated on the first joining surface of the first joining member, the assembly was heated under conditions of the temperature, pressure, holding time, and firing atmosphere shown in Table 1, the metal nanoparticles in the conductive joining material were fired to sinter them, and thereby a joining layer was formed between the first joining member and the second joining member to obtain the conductive joined structure of each of the examples and comparative examples. The conductive joined structures of the examples were as shown in FIG. 2. Further, the conductive joined structures of the comparative examples were as shown in FIG. 1.

In the joining layers of the conductive joined structures of the examples and comparative examples prepared in the above way, the majority of the content other than the metal material and the conductive material is the residue after carbonization by heating of the solvent and organic shells of the metal nanoparticles or the buried resin.

Measurement of Shear Strength

The conductive joined structures of the examples and comparative examples right after finishing being joined and prepared were cooled down to ordinary temperature, then measured for the shear strengths (n=10) of the Si semiconductor devices by the die shear mode using a bond tester (Series 4000 made by Dage). The results are shown in Table 1. In the examples of the present invention, in each case, the value was 10 MPa or more. As opposed to this, in the comparative examples, the shear strength was a low value of 10 MPa or less. As a result, in the conductive joined structures of the examples of the present invention, it was learned that the coefficient of thermal expansion of the joining layer is reduced and a good shear strength after joining is expressed.

Temperature Cycle Test

The conductive joined structures of the examples and comparative examples right after the joining operation is ended were subjected to a temperature cycle test using a gas phase type thermal shock tester (TSA-ES72-W made by Espec) and holding the structures at −40° C. and 250° C. for 30 minutes each. During this temperature cycle test, the conductive joined structures were taken out after the elapse of every 100 cycles and investigated for the states of peeling between the first joining member and the joining layer and between the joining layer and the second joining member using an ultrasonic video apparatus (FineSAT made by Hitachi Power Solutions). The structures were evaluated as “Good” when the rate of increase of peeling area after 1000 cycles was less than 20% based on the initial state and further as “Poor” when the rate of increase of peeling area was 20% or more. The results are shown in Table 1.

TABLE 1

| | | Metal joining material | | | | | | | | | | | |
|---|---|---|---|---|---|---|---|---|---|---|---|---|---|
| | | Metal | | Microparticles of | | | | | | | Joining | Evaluation of | |
| | | nanoparticles | | conductive material | | | | | | | layer | conductive | |
| | | | Average | | Average | Ratio of | Firing conditions at time of joining | | | | Thickness | joined structure | |
| | | | particle | | particle | total | | | | Atmosphere | after | Shear | |
| | | | size | | size | particles | Temperature | Pressure | Time | at time of | joining | strength | Temperature |
| | | Type | (nm) | Type | (μm) | (vol %) | (° C.) | (MPa) | (min) | firing | (μm) | (MPa) | cycle test |
| Ex. | 1 | Ag | 12 | W | 8 | 60 | 220 | 0 | 60 | Air | 45 | >10 | Good |
| | 2 | Cu | 60 | W | 3 | 55 | 280 | 1 | 30 | 3% H₂—N₂ | 60 | >10 | Good |
| | 3 | Ni | 90 | W | 3 | 40 | 320 | 0 | 60 | 3% H₂—N₂ | 120 | >10 | Good |
| | 4 | Ag | 12 | Mo | 10 | 10 | 230 | 5 | 60 | Air | 35 | >10 | Good |
| | 5 | Cu | 60 | Mo | 4 | 50 | 300 | 5 | 30 | 3% H₂—N₂ | 55 | >10 | Good |
| | 6 | Ni | 90 | Mo | 4 | 30 | 320 | 5 | 60 | 3% H₂—N₂ | 150 | >10 | Good |
| | 7 | Au | 8 | Cr | 1 | 55 | 250 | 0 | 60 | Air | 15 | >10 | Good |
| | 8 | Ni | 90 | W | 8 | 25 | 320 | 1 | 60 | 3% H₂—N₂ | 100 | >10 | Good |
| | | | | Mo | 4 | 10 | | | | | | | |
| | 9 | Ni | 80 | TiB₂ | 2 | 80 | 300 | 0 | 60 | 3% H₂—N | 130 | >10 | Good |
| | 10 | Ni | 80 | ZrB₂ | 2.5 | 80 | 300 | 0 | 60 | 3% H₂—N | 130 | >10 | Good |
| | 11 | Ni | 80 | TiB₂ | 2 | 35 | 300 | 0 | 60 | 3% H₂—N | 130 | >10 | Good |
| | | | | ZrB₂ | 2.5 | 35 | | | | | | | |
| | 12 | Ni | 80 | W | 3 | 35 | 300 | 0 | 60 | 3% H₂—N | 130 | >10 | Good |
| | | | | ZrB₂ | 2.5 | 35 | | | | | | | |
| Comp. | 1 | Ag | 12 | — | — | — | 220 | 0 | 60 | Air | 40 | 7 | Poor |
| ex. | 2 | Cu | 60 | — | — | — | 280 | 1 | 30 | 3% H₂—N₂ | 55 | 3 | Poor |
| | 3 | Ni | 90 | — | — | — | 300 | 0 | 60 | 3% H₂—N₂ | 100 | 5 | Poor |

In the comparative examples, the Si chips and joining layers completely peeled apart at the interface before 400 cycles, while in the examples of the present invention, no increase in peeling could be recognized up to 1000 cycles compared with the initial state.

### REFERENCE SIGNS LIST

1 . . . first joining member, 1a . . . first joining surface, 2 . . . second joining member, 2a . . . second joining surface, 3, 3a . . . joining layer, 4 . . . metal nanoparticle phase, 5 . . . metal microparticles.

1-12. (canceled)

13. A conductive joining material containing metal nanoparticles, microparticles of a conductive material, and a solvent, wherein the conductive material forming said microparticles has a linear thermal expansion coefficient smaller than the linear thermal expansion coefficient of the metal forming said nanoparticles and the microparticles of conductive material have an average particle size of 0.5 to 10 μm.

14. The conductive joining material according to claim 13, wherein said difference in linear thermal expansion coefficient between the metal forming the nanoparticles and the conductive material forming the microparticles is 5×10⁻⁶/K or more.

15. The conductive joining material according to claim 13, wherein said metal nanoparticles are any one of Ag, Au, Cu, and Ni.

16. The conductive joining material according to claim 13, wherein said microparticles of conductive material are one or more of a metal or metal boride.

17. The conductive joining material according to claim 13, wherein said microparticles of conductive material are one or more of any of W, Mo, Cr, TiB₂, and ZrB₂.

18. The conductive joining material according to claim 13, wherein 10 to 80 vol % of the total of the metal nanoparticles and microparticles of conductive material contained in said conductive joining material is comprised of said microparticles of conductive material.

19. A joining method using a conductive joining material comprising placing a conductive joining material according to claim 13 between the first joining member and second joining member and heating it to 450° C. or less to join said first joining member and said second joining member.

20. A conductive joined structure obtained by using a conductive joining material according to claim 13 to join a first joining member and a second joining member, wherein 2 to 90 mass % of the conductive material derived from said microparticles and the metal derived from said metal nanoparticles in the cross-section in the joining direction is said conductive material.

21. The conductive joined structure according to claim 20, wherein a difference in linear thermal expansion coefficients of said metal and said conductive material is 5×10⁻⁶/K or more.

22. The conductive joined structure according to claim 20, wherein said metal is any of Ag, Au, Cu, and Ni.

23. The conductive joined structure according to claim 20, wherein said conductive material is a conductive material of one or more of a metal or metal boride.

24. The conductive joined structure according to claim 20, wherein said conductive material is one or more of W, Mo, Cr, TiB₂, and ZrB₂.

25. The conductive joining material according to claim 14, wherein said metal nanoparticles are any one of Ag, Au, Cu, and Ni.

26. The conductive joining material according to claim 14, wherein said microparticles of conductive material are one or more of a metal or metal boride.

27. The conductive joining material according to claim 15, wherein said microparticles of conductive material are one or more of a metal or metal boride.

28. The conductive joining material according to claim 25, wherein said microparticles of conductive material are one or more of a metal or metal boride.

29. The conductive joining material according to claim 14, wherein said microparticles of conductive material are one or more of any of W, Mo, Cr, TiB₂, and ZrB₂.

30. The conductive joining material according to claim 15, wherein said microparticles of conductive material are one or more of any of W, Mo, Cr, TiB₂, and ZrB₂.

31. The conductive joining material according to claim 16, wherein said microparticles of conductive material are one or more of any of W, Mo, Cr, TiB₂, and ZrB₂.

32. The conductive joining material according to claim 25, wherein said microparticles of conductive material are one or more of any of W, Mo, Cr, TiB₂, and ZrB₂.
